(19) United States
(12) Patent Application Publication
(10) Pub. No.: US 2013/0075851 A1
(43) Pub. Date: Mar. 28, 2013

(54) SOLID-STATE IMAGING DEVICE

(71) Applicant: PANASONIC CORPORATION, Osaka (JP)

(72) Inventors: Yuka TERAI, Osaka (JP); Atsuo NAKAGAWA, Toyama (JP); Kazumi KURIMOTO, Toyama (JP)

(73) Assignee: PANASONIC CORPORATION, Osaka (JP)

(21) Appl. No.: 13/662,086

(22) Filed: Oct. 26, 2012

Related U.S. Application Data
(63) Continuation of application No. PCT/JP2011/001059, filed on Feb. 24, 2011.

(30) Foreign Application Priority Data
Jun. 4, 2010 (JP) 2010-129058

(51) Int. Cl. H01L 31/0232

(52) U.S. Cl. 257/432; 257/E31.127

(57) ABSTRACT

A solid-state imaging device includes a plurality of pixels arranged in a matrix pattern on a substrate. Each of the pixels includes a photoelectric conversion portion configured to convert incident light to an electric signal, an optical waveguide formed over the photoelectric conversion portion, an interlayer insulating film formed around the optical waveguide, and a color filter formed over the optical waveguide. The optical waveguide is configured so that light intensity distribution of light that has transmitted through the color filter has a single peak in a center of an upper surface of the photoelectric conversion portion. The plurality of pixels include at least two kinds of pixels that include the color filters configured to transmit light of different wavelength bands from each other therethrough.

### CROSS-REFERENCE TO RELATED APPLICATION

This is a continuation of PCT International Application PCT/JP2011/001059 filed on Feb. 24, 2011, which claims priority to Japanese Patent Application No. 2010-129058 filed on Jun. 4, 2010. The disclosures of these applications including the specifications, the drawings, and the claims are hereby incorporated by reference in their entirety.

### BACKGROUND

In recent years, as the number of pixels has been increased in solid-state imaging devices for use in digital still cameras etc., a photoelectric conversion element in each pixel has been reduced in size. Thus, efficient collection of incident light onto the photoelectric conversion elements is one of key factors in development of the solid-state imaging devices. In particular, if the size of one photoelectric conversion element is smaller than 1.5 μm, using only a microlens is not enough for collection of the incident light. Thus, it has been proposed to use an optical waveguide structure.

The “optical waveguide” refers to a structure including a portion having a higher refractive index (a core) than a peripheral portion (a cladding). This structure uses total reflection or Fresnel reflection of light at the interface between the core and the cladding to confine the light in the optical waveguide (the core). Thus, light diffusion is suppressed, and the incident light can be collected to a photoelectric conversion portion.

FIG. 11 shows an example of a solid-state imaging device using an optical waveguide (Japanese Patent Publication No. 2003-324189).

As shown in FIG. 11, a light receiving portion 2 and a channel region 17 are provided in the upper part of a substrate 1, and an interlayer insulating film 3a covers the light receiving portion 2 and the channel region 17. A gate electrode 16 is provided above the channel region 17 with a part of the interlayer insulating film 3a interposed therebetween. An interconnect 4a is provided above the gate electrode 16 so as to be buried in the upper part of the interlayer insulating film 3a. The side and bottom surfaces of the interconnect 4a are covered by a barrier film 7. A diffusion preventing film 5a is provided over the interlayer insulating film 3a so as to cover the interconnect 4a. An interlayer insulating film 3b is provided on the diffusion preventing film 5a, and an interconnect 4b is buried in the upper part of the interlayer insulating film 3b. The side and bottom surfaces of the interconnect 4b are covered by a barrier layer 7. A diffusion preventing film 5b is provided over the interlayer insulating film 3b so as to cover the interconnect 4b. Similarly, a structure formed by a barrier film 7, an interconnect 4c, an interlayer insulating film 3c, and a diffusion preventing film 5c is provided on the diffusion preventing film 5b.

The diffusion preventing films 5a, 5b, 5c, the interlayer insulating films 3b, 3c, etc., which are formed on the interlayer insulating film 3a, are removed in a region above the light receiving portion 2, and a passivation film 12 is buried in the resultant recess. Since no interfaces of the interlayer insulating films 3b, 3c, the diffusion preventing films 5a-5c, etc. are present above the light receiving portion 2, reflection of incident light 13 by such interfaces can be avoided. This improves efficiency of light incidence on the light receiving portion.

However, in the case of a solid-state imaging device including a plurality of pixels corresponding to different colors, waveform distribution of light that is incident on the optical waveguide is determined by the color filter that is provided above the optical waveguide. Accordingly, even if the shape and dimensions of the optical waveguide, the refractive index of the material forming the optical waveguide, etc. are the same, there is a possibility that the light intensity in the light receiving portion located at the terminal end of the optical waveguide is high enough in the pixel of one color, but is not high enough in the pixel of another color.

### SUMMARY

In view of the above, a technique will be described below which improves sensitivity of each color by increasing the light intensity in the light receiving portion of each pixel in the solid-state imaging device including a plurality of pixels corresponding to different colors.

The inventors conducted the following examinations.

In order for light to stably exist in the optical waveguide, it is required that the boundary conditions of Maxwell's electromagnetic equations be satisfied at the boundary between the core and the cladding. The optical wave that satisfies the boundary conditions and stably exists in the optical waveguide is called the “natural mode,” which is discrete. In the fundamental mode called the “single mode” of the natural mode, light intensity distribution is such that a single peak is located in the central portion in the lateral direction (the direction perpendicular to the propagation direction of the optical wave) of the optical waveguide.

In the optical waveguide, there are a position where the single mode appears and a position where a multi-order mode appears, depending on the position in the propagation direction. The maximum light intensity is obtained in the single mode.

Thus, the inventors had the idea of improving the sensitivity (the magnitude of an output electric signal of an output portion with respect to incident light) by configuring the optical waveguide in the pixel of each color so that the single mode appears at the surface of the light receiving portion.

Specifically, the solid-state imaging device according to the present disclosure includes: a plurality of pixels arranged in a matrix pattern on a substrate, wherein each of the pixels includes a photoelectric conversion portion configured to convert incident light to an electric signal, an optical waveguide formed over the photoelectric conversion portion, an interlayer insulating film formed around the optical waveguide, and a color filter formed over the optical waveguide, the optical waveguide is configured so that light intensity distribution of light that has transmitted through the color filter has a single peak in a center of an upper surface of the photoelectric conversion portion, and the plurality of pixels include at least two kinds of pixels that include the color filters configured to transmit light of different wavelength bands from each other therethrough.

According to this solid-state imaging device, light intensity distribution having high intensity near the center of the upper surface of the photoelectric conversion portion is implemented for each of the plurality of kinds of pixels corresponding to light of the different wavelength bands (light of different colors), and sensitivity can be improved.

The at least two kinds of pixels may include the optical waveguides having different widths from each other.

As one method to optimize the optical waveguide of each pixel, the width of the optical waveguide (the dimension in a direction parallel to a principal surface of the substrate; e.g., the length of the side of the base if the optical waveguide is in the shape of a cuboid, the diameter of the optical waveguide if the optical waveguide is in the shape of a cylinder, etc.) may be varied according to the corresponding wavelength band of light.

The at least two kinds of pixels may include a red pixel including the color filter configured to transmit red light therethrough, a blue pixel including the color filter configured to transmit blue light therethrough, and a green pixel including the color filter configured to transmit green light therethrough, and the width of the optical waveguide may be increased in order of the red, green, and blue pixels.

This configuration can improve the sensitivity of the pixel of each color in a primary color solid-state imaging device.

The optical waveguides of the at least two kinds of pixels may be comprised of materials having different refractive indices from each other.

As one method to optimize the optical waveguide of each pixel, the material of the optical waveguide may be varied according to the corresponding wavelength band of light.

The pixel having the color filter configured to transmit the light of a shorter wavelength band may have the optical waveguide comprised of the material having a lower refractive index.

The at least two kinds of pixels may include a red pixel including the color filter configured to transmit red light therethrough, a blue pixel including the color filter configured to transmit blue light therethrough, and a green pixel including the color filter configured to transmit green light therethrough, and the refractive index of the material of the optical waveguide may be increased in order of the blue, green, and red pixels.

The relation between the kind of pixel and the material (the refractive index) of the optical waveguide may be as described above.

The at least two kinds of pixels may include the optical waveguides having different heights from each other.

As one method to optimize the optical waveguide of each pixel, the height of the optical waveguide may be varied according to the corresponding wavelength band of light.

The pixel having the color filter configured to transmit the light of a shorter wavelength band may have the optical waveguide having a greater height (a larger dimension in a direction perpendicular to the principal surface of the substrate).

The at least two kinds of pixels may include a red pixel including the color filter configured to transmit red light therethrough, a blue pixel including the color filter configured to transmit blue light therethrough, and a green pixel including the color filter configured to transmit green light therethrough, and the height of the optical waveguide may be decreased in order of the red, green, and blue pixels.

The relation between the kind of pixel and the height of the optical waveguide may be as described above.

The optical waveguide may be in a shape of a cuboid or a cylinder.

Specific examples of the shape of the optical waveguide include a cuboid and a cylinder. The optical waveguide may be in the shape of a rectangular prism having a square base.

Each of the pixels may further include a microlens provided above the optical waveguide, and the color filter may be located between the optical waveguide and the microlens or on the microlens.

According to the solid-state imaging device described above, the configuration of the optical waveguide is designed for each of the plurality of kinds of pixels corresponding to light of the different wavelength bands (colors), whereby the sensitivity of every pixel can be improved.

### BRIEF DESCRIPTION OF THE DRAWINGS

FIG. 1 is a diagram showing the simulation result of the relation between the position in the propagation direction and the positions where a single mode and a multi-order mode appear in an optical waveguide, and light intensity distribution at each position.

FIG. 2 is a plan view showing pixels arranged in a matrix pattern in an example solid-state imaging device of the present disclosure.

FIGS. 3A-3B are schematic sectional views corresponding to lines X-X′ and Y-Y′ in FIG. 2, respectively, showing an example solid-state imaging device according to a first embodiment of the present disclosure.

FIGS. 4A-4B are diagrams illustrating a manufacturing method of the example solid-state imaging device shown in FIGS. 3A-3B.

FIGS. 5A-5B are schematic sectional views corresponding to lines X-X′ and Y-Y′ in FIG. 2, respectively, showing an example solid-state imaging device according to a second embodiment of the present disclosure.

FIGS. 6A-6B are diagrams illustrating a manufacturing method of the example solid-state imaging device shown in FIGS. 5A-5B.

FIGS. 7A-7B are schematic sectional views corresponding to lines X-X′ and Y-Y′ in FIG. 2, respectively, showing an example solid-state imaging device according to a third embodiment of the present disclosure.

FIGS. 8A-8B are diagrams illustrating a manufacturing method of the example solid-state imaging device shown in FIGS. 7A-7B.

FIGS. 9A-9B are diagrams illustrating the manufacturing method of the example solid-state imaging device shown in FIGS. 7A-7B, subsequently to FIGS. 8A-8B.

FIGS. 10A-10B are diagrams illustrating the manufacturing method of the example solid-state imaging device shown in FIGS. 7A-7B, subsequently to FIGS. 9A-9B.

FIG. 11 is a diagram showing a solid-state imaging device of related art.

### DETAILED DESCRIPTION

First, an optical waveguide will be described in order to describe a solid-state imaging device of the present disclosure.

In the optical waveguide, the wavelength of a wave propagating to a silicon surface (the upper surface of a photoelectric conversion portion formed in a silicon substrate; if there is a surface depletion inhibiting region etc., the upper surface thereof) is determined by the shape and dimensions of the optical waveguide, the refractive indices of materials forming a core (inside of the optical waveguide) and a cladding (an outer portion), etc. This is because, in order for light to stably exist in the optical waveguide, it is required that the boundary conditions of Maxwell's electromagnetic equations be satisfied at the boundary between the core and the cladding (each of tangential components of E (electric field) and B (magnetic field) be equal on both sides of the boundary). The optical wave that satisfies the boundary conditions and stably exists in the optical waveguide is called the “natural mode,” which is discrete. That is, only light of the wavelengths stably exist in the optical waveguide. Moreover, in the fundamental mode called the “single mode” of the natural mode, the light intensity distribution is such that the light intensity is high in the central portion in the lateral direction (the direction perpendicular to the propagation direction of the optical wave) of the optical waveguide.

In the zero-order single mode, the light intensity is high in the central portion of the optical waveguide. However, in a multi-order mode such as the first-order mode or the second-order mode, the light intensity is higher in the peripheral portion of the optical waveguide than in the central portion thereof. These modes interfere with each other and are superimposed on each other, thereby propagating in the optical waveguide. As a result, there are a position where the single mode appears and a position where the multi-order mode appears, depending on the position in the propagation direction. The maximum light intensity is obtained at the position where the single mode appears.

The inventors had the following idea based on the above. In order to improve sensitivity characteristics of imaging devices, the optical waveguides are designed so that light in the single mode is located in the photoelectric conversion portion at the silicon surface to suppress excessive spreading of light. Based on this idea, the inventors conducted simulation of sensitivity of green pixels (three-dimensional wave simulation), and confirmed that the highest green sensitivity was obtained when the single mode is matched with the silicon surface.

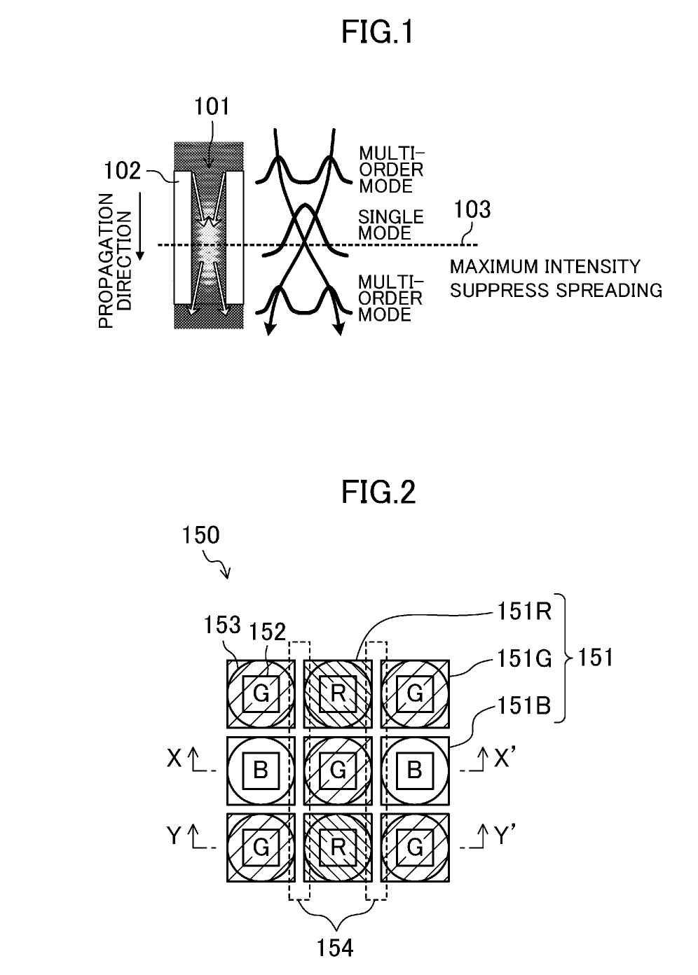

FIG. 1 shows the result of the optical wave simulation. FIG. 1 schematically shows the structure including an optical waveguide 101 comprised of a material having a refractive index of 1.9, and a portion 102 (corresponding to a cladding layer) surrounding the optical waveguide 101 and comprised of a material having a refractive index of 1.2. FIG. 1 shows an example in which green light (wavelength: about 550 nm) is incident from above in the figure, and the difference in electric field strength |E|² among the positions is shown by the darkness of the color.

The mode that appears and the light intensity distribution in a plane perpendicular to the propagation direction vary depending on the position in the propagation direction of incident light. In this example, the single mode appears in a predetermined plane 103 in the optical waveguide 101, and at this position, the light intensity increases in the central portion of the optical waveguide 101. In other words, the peak of the light intensity is located in the central portion of the optical waveguide 101. Accordingly, if the upper surface of the photoelectric conversion portion is located at the position of the predetermined plane 103, the incident light is collected to the central portion of the photoelectric conversion portion, and is prevented from spreading outward. As a result, a sufficient amount of incident light can be received, and satisfactory sensitivity characteristics can be obtained.

Pixels corresponding to different colors are provided with color filters configured to transmit light of different wavelength bands therethrough, and the wavelength of light that is incident on the optical waveguide is determined by the color filter. More precisely, wavelength distribution of light that is incident on the optical waveguide is determined by wavelength dependence of the light absorption ratio of the color filter provided above the optical waveguide (which is called “wavelength dispersion”). Thus, if the shape and dimensions of the optical waveguide, the refractive index in the optical waveguide, etc. are exactly the same in each of the pixels of different colors, optimal sensitivity cannot be obtained in all of the pixels. For example, even if the highest sensitivity is obtained in the green pixels, the highest sensitivity cannot be obtained in the blue and red pixels. This is for the following reason. Even if the optical waveguide has the same structure, the position where the single mode appears varies due to the difference in wavelength of incident light. Thus, the position of the single mode cannot be matched with the upper surface of the photoelectric conversion portion in all of the plurality of kinds of pixels.

Accordingly, sensitivity can be improved in all of the pixels corresponding to different wavelength bands of light by optimizing the optical waveguides for each of the wavelength bands (wavelength dispersion of the color filter provided in each of the pixels) and providing such optimized optical waveguides in the pixels. Embodiments of the solid-state imaging device based on this idea will be described below.

### First Embodiment

An example solid-state imaging device (a charge coupled device (CCD) as an example) according to a first embodiment will be described with reference to the accompanying drawings.

FIG. 2 is a partial enlarged plan view of an imaging region in an example solid-state imaging device 150. More specifically, FIG. 2 is a schematic view of a plurality of pixels 151 arranged in a matrix pattern. Each pixel 151 as a basic unit includes a photoelectric conversion portion 152 configured to carry out photoelectric conversion, a microlens 153, etc., and vertical transfer registers 154 are provided in the imaging region.

If color separation of incident light is not performed in the solid-state imaging device, only a monochrome image can be obtained from a photoelectrically converted signal. In order to obtain a color image, color separation is performed in the solid-state imaging device such as a CCD by using a plurality of kinds of color filters that transmit light of different wavelength bands therethrough.

For example, red pixels 1518, blue pixels 151B, and green pixels 151G are provided so that each pixel includes one of color filters that transmit light of a red, blue, or green wavelength band therethrough. Colors of an original image are reproduced by superimposing on each other an image obtained by the red pixels 151R, an image obtained by the blue pixels 151B, and an image obtained by the green pixels 151G.

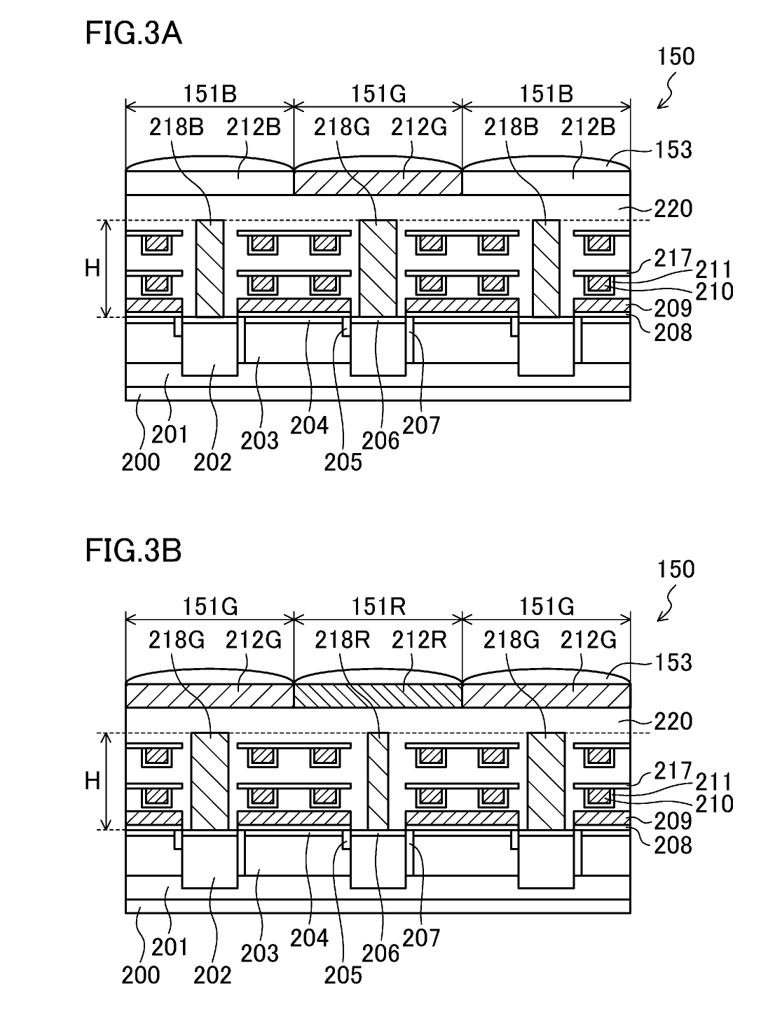

Light that is transmitted through a red color filter 212R (see FIG. 3B) has a wavelength in the range of, e.g., 650±30 nm (center wavelength: 650 nm). Similarly, light that is transmitted through a blue color filter 212B (see FIG. 3A) has a wavelength in the range of, e.g., 450±30 nm (center wavelength: 450 nm), and light that is transmitted through a green color filter 212G (see FIGS. 3A-3B) has a wavelength in the range of, e.g., 550±30 nm (center wavelength: 550 nm). These values are shown by way of illustration only, and these wavelengths may have any other values in the range corresponding to red, blue, or green.

In the example of FIG. 2, the pixels of each color are arranged in a regular two-dimensional array called a Bayer array.

Specifically, in the lateral direction, the pixels are arranged in the order of blue, green, and blue in one row (e.g., the row of X-X′ in FIG. 2), and are arranged in the order of green, red, and green in an adjoining row (e.g., the row of Y-Y′ in FIG. 2). In the vertical direction as well, the pixels are arranged in the order of blue, green, and blue in one column, and are arranged in the order of green, red, and green in an adjoining column. Moreover, every pixel adjoining the green pixel 151G in the lateral or vertical direction is always either the blue pixel 151B or the red pixel 151R, and no red pixel 151R is present in the same row or column as the blue pixels 151B. Although a total of 9 pixels 151 are shown in FIG. 2, a larger number of pixels are arranged in an actual configuration.

In such a Bayer array, the number of green pixels 151G is twice as large as each of the number of red pixels 151R and the number of blue pixels 151B. This is because human eyes are sensitive to green light, and using the larger number of green pixels 151G can increase resolution of a shot image.

FIGS. 3A-3B show schematic cross sections of the solid-state imaging device 150. FIG. 3A shows a cross section taken along line X-X′ in FIG. 2 (a cross section along the row of the blue pixel 151B, the green pixel 151G, and the blue pixel 151B), and FIG. 3B shows a cross section taken along line Y-Y′ in FIG. 2 (a cross section along the row of the green pixel 151G, the red pixel 151R, and the green pixel 151G).

The solid-state imaging device 150 is formed by using an N-type silicon substrate 200, and the red pixels 151R, the blue pixels 151B, and the green pixels 151G are arranged in the solid-state imaging device 150. A P-type first well region 201 is provided on the silicon substrate 200, and N-type charge accumulation regions 202 are provided on the P-type first well region 201 so as to correspond to each pixel. Surface depletion inhibiting regions 206 are provided so as to cover the charge accumulation regions 202. A Vt control region 205 is provided on one side of each charge accumulation region 202, and a channel stop region 207 is provided on the other side thereof. The channel stop region 207 is provided in order to suppress entrance of noise charge into an adjoining pixel. P-type second well regions 203 are provided on the first well region 201 so that each second well region 203 is located between the charge accumulation regions 202 of adjoining ones of the pixels. Transfer channel regions 204 are provided on the second well regions 203.

A gate electrode 209 configured to drive a vertical transfer CCD is formed on each transfer channel region 204 with a gate insulating film 208 interposed therebetween. An interlayer insulating film 220 is provided so as to cover the gate electrodes 209, the charge accumulation regions 202, etc. Copper interconnects 210 configured to apply a drive voltage to the gate electrode 209 are provided above the gate electrodes 209 in the interlayer insulation film 220. In order to suppress or prevent diffusion of copper, the side and lower surfaces of each copper interconnect 210 are covered by a barrier film 211 and the upper surface of each copper interconnect 210 is covered by a barrier film 217.

In each pixel, an optical waveguide is provided above the charge accumulation region 202 configured to perform photoelectric conversion, and a color filter and a microlens are provided on the interlayer insulating film 220 so as to be located above the optical waveguide. A red pixel optical waveguide 218R and the red color filter 212R are provided in each red pixel 151R, a blue pixel optical waveguide 218B and the blue color filter 212B are provided in each blue pixel 151B, and a green pixel optical waveguide 218G and the green color filter 212G are provided in each green pixel 151G.

The optical waveguides and the color filters, which are provided in the three kinds of pixels (151R, 151B, and 151G), are sometimes generally referred to as the “optical waveguides 218” and the “color filters 212.” The optical waveguide 218 corresponds to a core portion, and the interlayer insulating film 220 surrounding the optical waveguide 218 corresponds to a cladding layer.

The charge accumulation region 202 functions as a photoelectric conversion portion (a photodiode portion) that changes light into electric charge. Any interface state on the charge accumulation region 202 (a silicon surface portion) due to a surface defect causes a dark current. The P-type surface depletion inhibiting region 206 is provided in order to prevent the influence of the dark current. A similar advantage can be obtained by providing an etching stopper such as, e.g., a silicon oxide film or a silicon nitride film (which is used to form an opening when forming an optical waveguide) on the silicon surface, instead of providing the surface depletion inhibiting region 206.

The entire optical waveguide 218 of the pixel 151 of each color is included in the rectangle of the charge accumulation region 202 as viewed from the upper surface. The lower end of the optical waveguide 218 is in contact with the surface depletion inhibiting region 206 provided in the silicon surface. The optical waveguides 218 in the pixels 151 of each color have the same height (the dimension in the propagation direction of optical waves), and have different widths. This will be described in more detail later.

In the solid-state imaging device 150 having the above configuration, light that is incident on the imaging region where the pixels are arranged is collected to the center of each pixel 151 by the microlens 153. The collected incident light is transmitted through the color filter 212 (212R, 212B, 212G) below the microlens 153, and then is confined in the optical waveguide 218 (218R, 218B, 218G). Thereafter, the light propagates in the optical waveguide 218, and then enters the charge accumulation region 202 and is absorbed by the charge accumulation region 202. The light thus absorbed is photoelectrically converted to electric charge and is accumulated in the charge accumulation region 202. The accumulated electric charge is transferred as an electric signal through the transfer channel region 204 in response to voltage application to the gate electrode 209.

In order to obtain satisfactory sensitivity characteristics, it is required to efficiently collect incident light to the charge accumulation region 202 to obtain an electric signal, even if the incident light is weak. For this purpose, it is important to cause the light to reach the charge accumulation region 202 so as not to allow the light to travel to any portion other than the main path described above.

If light is not sufficiently confined in the optical waveguide 218 (the core), the light is absorbed or reflected by a portion other than the optical waveguide 218, such as, e.g., the interlayer insulation film 220 as the cladding layer, whereby sensitivity is reduced. Reduction in sensitivity is also caused by absorption or reflection of light by the copper interconnect 210 configured to apply a voltage to the gate electrode 209, the barrier films 211, 217 configured to suppress diffusion of copper from the copper interconnect 210, in addition to the interlayer insulating film 220.

In order to sufficiently confine light in the optical waveguide, the material in the optical waveguide is required to have a higher refractive index than that of the material surrounding the optical waveguide. The larger the difference in refractive index therebetween, the higher the effect of light confinement is. Thus, the interlayer insulating film 220 as a cladding has a refractive index of, e.g., about 1.0 to 1.3 (a silicon oxide film formed by a plasma chemical vapor deposition (CVD) method, etc.), and the optical waveguide 218 (218R, 218B, 218G) is filled with a material having a refractive index as high as about 1.9-2.0. Such a refractive index can be implemented by using, e.g., an organic material, a silicon nitride film, etc.

The inventors have recognized that if an optical wave propagating in the optical waveguide 218 toward the charge accumulation region 202 has an antinode at the silicon surface and the light travels outward in the optical waveguide 218, the light spreads in a region other than the charge accumulation region 202, thereby causing reduction in sensitivity. Thus, the inventors have found a way to avoid such reduction in sensitivity. The inventors have also recognized that since the wavelength of the light incident on the optical waveguide 218 varies depending on the color of the pixel, an appropriate configuration of the optical waveguide 218 also varies depending on the color of the pixel. This will be described with respect to a specific example.

As shown in FIGS. 3A-3B, in the solid-state imaging device 150 of the present embodiment, the red pixel optical waveguide 218R, the blue pixel optical waveguide 218B, and the green pixel optical waveguide 218G have the same height H from the silicon surface to their respective upper surfaces. Specifically, the height H is in the range of, e.g., 600 nm to 650 nm, both inclusive.

In the case where each optical waveguide 218 is in the shape of a cuboid, and more specifically in the shape of a rectangular prism having a square base, optimal sensitivity is obtained when the width (the length of the side of the base) of the optical waveguide 218 is in the range of 300 nm to 800 nm, both inclusive.

According to optical wave simulation, the position of the single mode can be matched with the silicon surface when the width of the green pixel optical waveguide 218G is in the range of 700 nm to 740 nm, both inclusive. In this case, the optical wave in the optical waveguide has a node at the silicon surface, and a peak of light intensity distribution is located in the central portion. Accordingly, the light does not spread and is absorbed by the charge accumulation region 202, whereby high sensitivity can be implemented. The most desirable width of the optical waveguides 218 is 720 nm.

Similarly, the position of the single mode can be matched with the silicon surface and high sensitivity can be implemented when the width of the blue pixel optical waveguide 218B is in the range of 580 nm to 620 nm, both inclusive (the most desirable width is 600 nm), and when the width of the red pixel optical waveguide 218R is in the range of 500 nm to 540 nm, both inclusive (the most desirable width is 520 nm). The most desirable height of the optical waveguides 218 is 600 nm.

In the case where each optical waveguide 218 is in the shape of a cylinder, optimal sensitivity is obtained when the diameter of the optical waveguide 218 is in the range of 350 nm to 850 nm, both inclusive. In this case, the natural mode is different from the case where each optical waveguide 218 is in the shape of a cuboid, due to the difference in shape. According to the optical wave simulation, the value of a desired diameter of the optical waveguide 218 is different by about ±50 nm (from the value of the width of each optical waveguide 218 in the case where each optical waveguide 218 is in the shape of a cuboid). Specifically, in the case where each optical waveguide 218 is in the shape of a cylinder, it is most desirable that the green pixel optical waveguide 218G have a diameter of 770 nm, the blue pixel optical waveguide 218B have a diameter of 670 nm, the red pixel optical waveguide 218R have a diameter of 570 nm, and each optical waveguide 218 have a height of 600 nm.

In this manner, satisfactory sensitivity characteristics can be implemented for all of the green, red, and blue pixels 151G, 151R, and 151B. The desired height and width of each optical waveguide 218 vary depending on various conditions such as, e.g., the materials and refractive indices of the cladding and the core (the interlayer insulting film 220 and the optical waveguide 218).

Although a CCD is described above as an example of the solid-state imaging device 150, the present invention is not limited to this, and the configuration of the present embodiment is also applicable to, e.g., a complementary metal oxide semiconductor (CMOS) sensor in which a CMOS transistor is connected in each pixel. Since the CMOS sensor includes an amplifier in each unit pixel, the CMOS sensor is characterized in that no noise is transferred, and that generation of electric noise due to reading of a photoelectrically converted electric signal can be suppressed.

Although the present embodiment is described with respect to an example in which the solid-state imaging device 150 includes the pixels of primary colors, namely blue, red, and green, the solid-state imaging device 150 may be configured to include pixels of complementary colors. The “complementary colors” refers to the colors located opposite each other in the color circle, and the complementary colors of the three primary colors (blue, red, and green) are yellow, magenta, and cyan, respectively. Actually, color filters of four colors, namely yellow, magenta, cyan, and green, are used in many video applications. This configuration uses color conversion, and thus has lower color reproducibility. However, since complementary color filters absorb less light than primary color filters, a bright image can be more easily obtained by the complementary color filters.

Optical waveguides having different widths can be provided by, e.g., forming, in the interlayer insulating film 220, openings having different dimensions for forming the optical waveguides, and burying the openings by a core material. This will be described below.

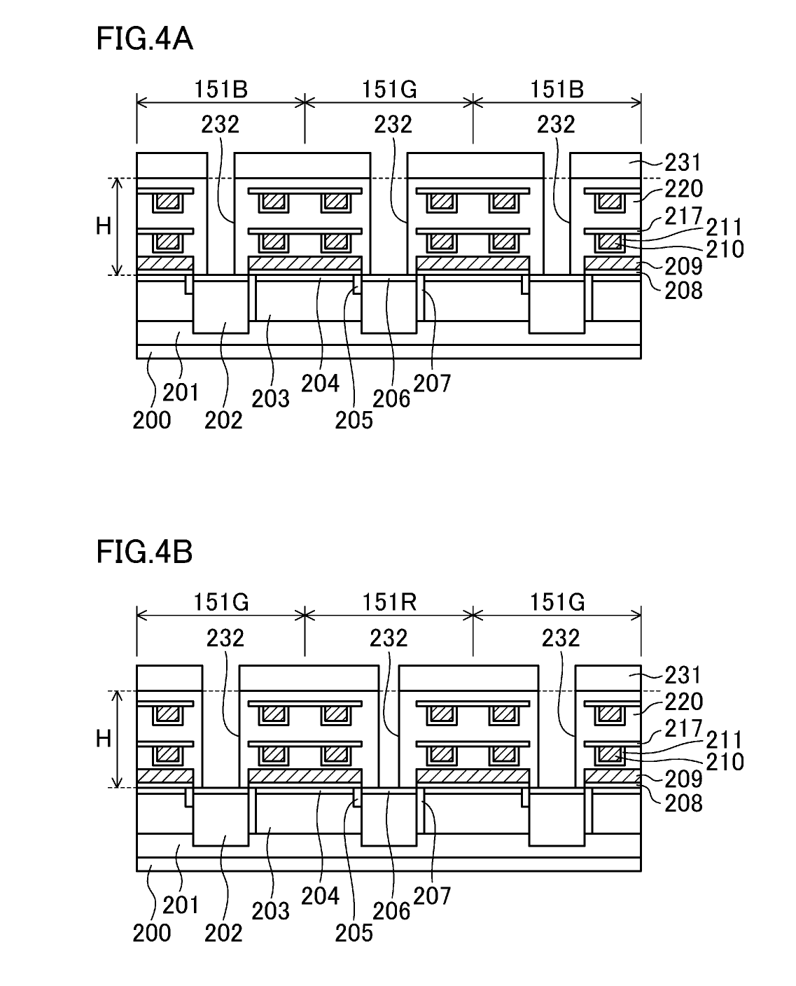

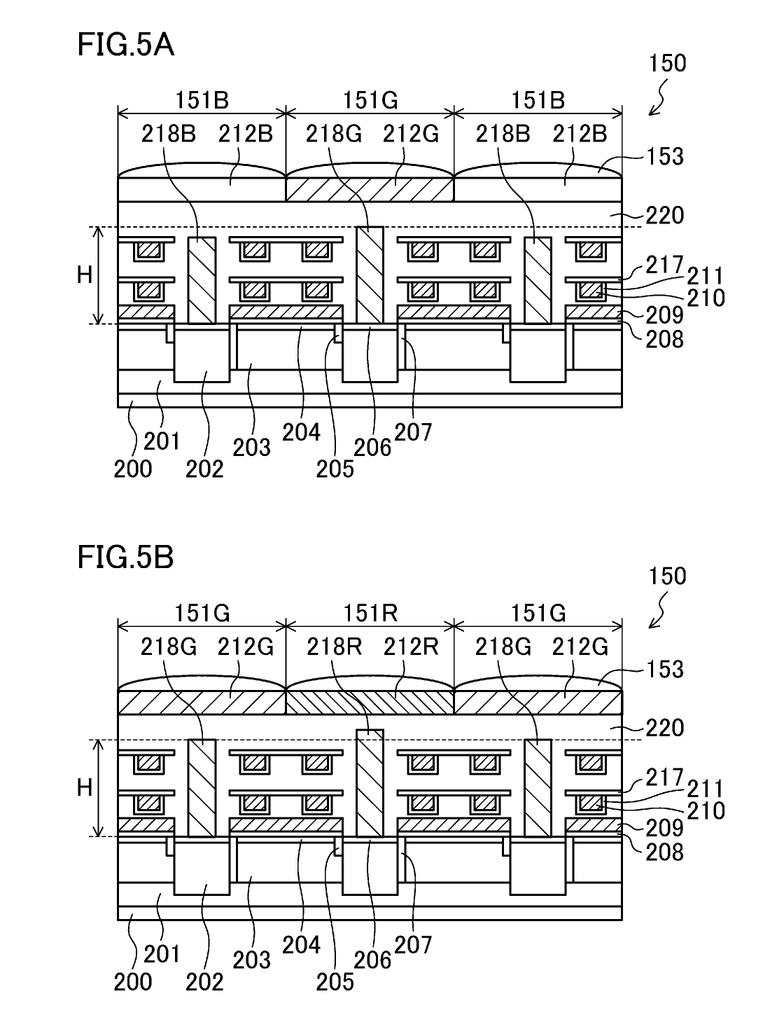

FIGS. 4A-4B are diagrams corresponding to FIGS. 3A-3B, respectively, showing the solid-state imaging device 150 during manufacturing. In order to manufacture the solid-state imaging device 150, the first well region 201, the charge accumulation regions 202, the second well regions 203, the transfer channel regions 204, the Vt control regions 205, the surface depletion inhibiting regions 206, the channel stop regions 207, etc. are first formed by impurity implantation to the silicon substrate 200, etc. Moreover, an insulating film and a conductive film are stacked and then patterned to form the gate oxide films 208 and the gate electrodes 209. Thereafter, the interlayer insulating film 220, and the copper interconnects 210 and the barrier films 211, 217, which are buried in the interlayer insulating film 220, are formed. Although the interlayer insulating film 220 is shown as a single layer in the figures, the interlayer insulating film 220 is formed as a stacked structure formed by a plurality of layers.

Then, as shown in FIGS. 4A-4B, a resist 231 is formed which has an opening with predetermined dimensions and shape above the charge accumulation region 202 of each pixel. The “predetermined dimensions and shape” refers to the dimensions and shape of each optical waveguide described in the present embodiment. Then, etching is performed by using the resist 231 as a mask, thereby forming openings 232 for forming the optical waveguides. The openings 232 are filled with a core material (a material having a higher refractive index than the interlayer insulating film 220).

Subsequently, a portion of the interlayer insulation film 220 which is located over the optical waveguides, the color filters 212, and the microlenses 153 are sequentially formed. Each color filter 212 is formed by using, e.g., an organic material containing a pigment of a predetermined color. The microlenses 153 are formed by applying an organic material having a refractive index of about 1.5-1.7, and then performing processes such as heat flow and hardening.

As described above, setting the dimensions of the openings in the resist 231 that is used in the etching step to form the optical waveguides allows an optimal structure of each optical waveguide to be implemented without increasing the number of steps.

### Second Embodiment

An example solid-state imaging device of a second embodiment will be described below with reference to the drawings.

An example solid-state imaging device 150a of the present embodiment also has an imaging region that includes pixels of each color arranged in a Bayer array as shown in FIG. 2. FIGS. 5A-5B show schematic cross sections corresponding to lines X-X′ and Y-Y′ in FIG. 2. In FIGS. 5A-5B, the same components as those of the solid-state imaging device 150 of the first embodiment shown in FIGS. 3A-3B are denoted with the same reference characters. The structure of the optical waveguides 218, which is a difference from the first embodiment, will be mainly described in detail below.

In the solid-state imaging device 150 of the first embodiment shown in FIGS. 3A-3B, the optical waveguides in the pixels of each color have different widths and the same height.

On the other hand, in the solid-state imaging device 150a of the present embodiment, the optical waveguides in the pixels of each color have different heights and the same width. This configuration also allows the position of the single mode to be matched with the silicon surface in the optical waveguide of each pixel, whereby high sensitivity can be implemented.

The solid-state imaging device 150a will be described below with respect to a specific example in which the green pixel optical waveguide 218G, the blue pixel optical waveguide 218B, and the red pixel optical waveguide 218R are in the shape of a cuboid, and more specifically in the shape of a rectangular prism having a square base, and have a width (the length of the side of the base) in the range of 700 nm to 720 nm, both inclusive. In this case, the solid-state imaging device 150a is configured so that the optical waveguides in the pixels of each color have different heights from each other from the silicon surface to the upper surface of the optical waveguide, and that the heights are in the range of 400 nm to 900 nm, both inclusive.

According to the optical wave simulation, the position of the single mode can be matched with the silicon surface when the height of the green pixel optical waveguide 218G is in the range of 600 nm to 640 nm, both inclusive. In this case, the optical wave in the optical waveguide has a node at the silicon surface, and a peak of light intensity distribution is located in the central portion. Accordingly, the light does not spread and is absorbed by the charge accumulation region 202, whereby high sensitivity can be implemented. The most desirable height of the green pixel optical waveguide 218G is 620 nm.

Similarly, the position of the single mode can be matched with the silicon surface and high sensitivity can be implemented when the height of the blue pixel optical waveguide 218B is in the range of 540 nm to 580 nm, both inclusive (the most desirable height is 560 nm), and when the height of the red pixel optical waveguide 218R is in the range of 650 nm to 690 nm, both inclusive (the most desirable height is 670 nm). The most desirable width of the optical waveguides 218 is 710 nm.

In the case where each optical waveguide 218 is in the shape of a cylinder, the natural mode is different from the case where each optical waveguide 218 is in the shape of a cuboid, due to the difference in shape. According to the optical wave simulation, the value of the desired height of each optical waveguide 218 is different by about ±50 nm (from the value of the desired height of each optical waveguide 218 in the case where each optical waveguide 218 is in the shape of a cuboid). Specifically, in the case where each optical waveguide 218 is in the shape of a cylinder, it is most desirable that the green pixel optical waveguide 218G have a height of 670 nm, the blue pixel optical waveguide 218B have a height of 610 nm, the red pixel optical waveguide 218R have a height of 720 nm, and each optical waveguide 218 have a diameter of 710 nm.

In this manner, satisfactory sensitivity characteristics can be implemented for all of the green, red, and blue pixels 151G, 151R, and 151B.

As in the example of the first embodiment, a CMOS sensor etc. may be used as the solid-state imaging device 150a instead of a CCD, pixels of complementary colors may be used instead of pixels of primary colors, etc.

In the solid-state imaging device 150a of the present embodiment, the optical waveguides have a width of, e.g., 710 nm. Thus, the solid-state imaging device 150a of the present embodiment can also be used in fine cells in which the charge accumulation regions 202 have a size of 710 nm by 710 nm as viewed from above.

The optical waveguides having different heights can be implemented by, e.g., burying openings formed in the interlayer insulating film 220 with a core material, and then removing a part of the upper portion of the core material.

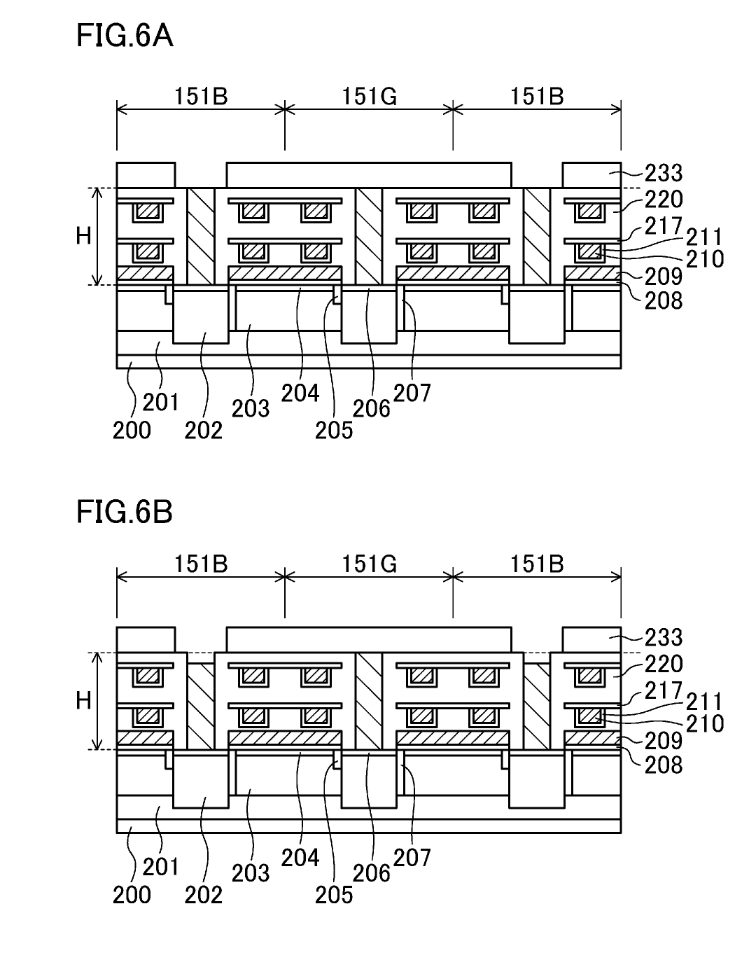

This is shown in FIGS. 6A-6B. FIG. 6A is a diagram showing the solid-state imaging device 150a during manufacturing, and corresponds to line X-X′ in FIG. 2. In FIG. 6A, a core material is buried in the openings formed in the interlayer insulating film 220, whereby the optical waveguides having the same width and the same height are formed in the green pixel 151G and the blue pixel 151B. A resist 233 is also formed so as to cover the optical waveguide of the green pixel 151G and to have an opening on the optical waveguide of the blue pixel 151B.

Then, etching is performed by using the resist 233 as a mask, whereby a part of the upper portion of the optical waveguide in the blue pixel 151B is removed as shown in FIG. 6B. In this manner, optical waveguides having different heights can be provided in the pixels of each color. The optical waveguides having three or more different heights can be implemented by repeating a similar process.

Thereafter, a portion of the interlayer insulating film 220 which is located over the optical waveguides, the color filters 212, and the microlenses 153 are sequentially formed in a manner similar to that described in the first embodiment.

### Third Embodiment

An example solid-state imaging device of a third embodiment will be described below with reference to the drawings.

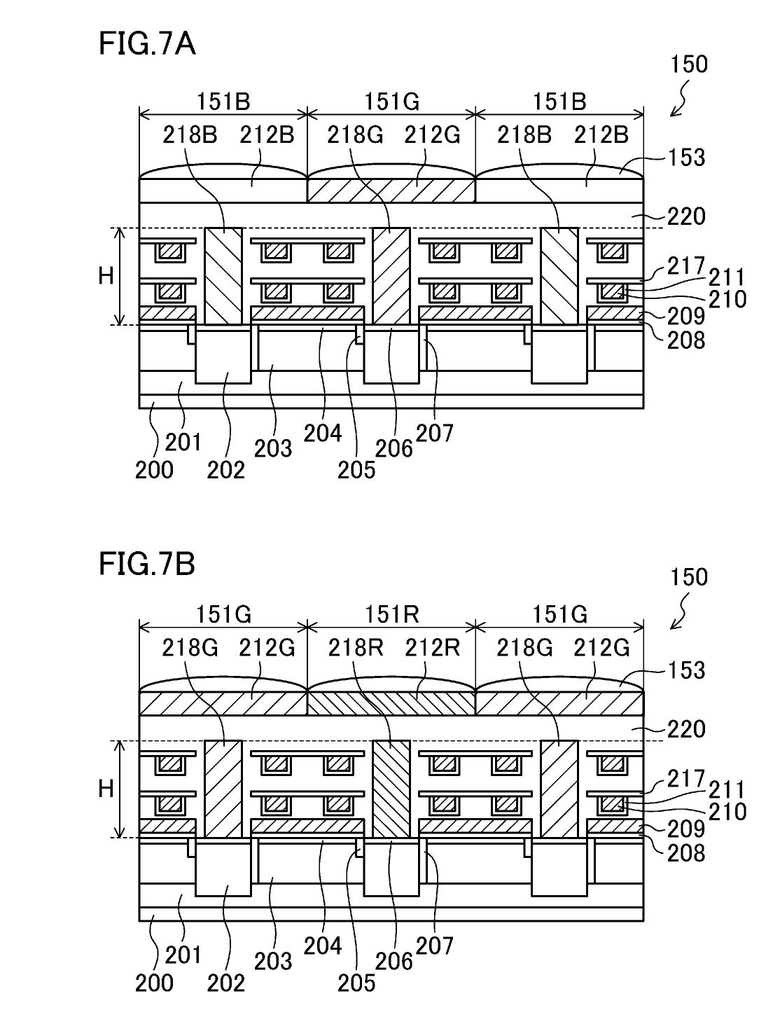

An example solid-state imaging device 150b of the present embodiment also has an imaging region that includes pixels of each color arranged in a Bayer array as shown in FIG. 2. FIGS. 7A-7B show schematic cross sections corresponding to lines X-X′ and Y-Y′ in FIG. 2. In FIGS. 7A-7B, the same components as those of the solid-state imaging device 150 of the first embodiment shown in FIGS. 3A-3B are denoted with the same reference characters. The structure of the optical waveguides 218, which is a difference from the first embodiment, will be mainly described in detail below.

In the first and second embodiments, the optical waveguides in the pixels of each color have different widths or heights.

On the other hand, in the solid-state imaging device 150b of the present embodiment, the optical waveguides in the pixels of each color have the same height and the same width, but have different refractive indices. This configuration also allows the position of the single mode to be matched with the silicon surface in the optical waveguide of each pixel, whereby high sensitivity can be implemented.

The solid-state imaging device 150b will be described below with respect to a specific example in which the green pixel optical waveguide 218G, the blue pixel optical waveguide 218B, and the red pixel optical waveguide 218R are in the shape of a cuboid, and more specifically in the shape of a rectangular prism having a square base, and have a width (the length of the side of the base) in the range of 700 nm to 720 nm, both inclusive, and a height in the range of 600 nm to 620 nm, both inclusive.

The interlayer insulating film 220 serving as a cladding of each optical waveguide has a refractive index of 1.2-1.3.

In this case, the solid-state imaging device 150b is configured so that the refractive indices of the core materials filling the optical waveguides in the pixels of each color are different from each other by an amount in the range of, e.g., 1.7 to 2.3, both inclusive.

According to the optical wave simulation, an optimal refractive index of the core material is 2.2 for the green pixel optical waveguide 218G, 1.8 for the blue pixel optical waveguide 218G, and 2.6 for the red pixel optical waveguide 218R. In this case, the position of the single mode can be matched with the silicon substrate in each optical waveguide. At this time, the optical wave in the optical waveguide has a node at the silicon surface, and a peak of light intensity distribution is located in the central portion. Accordingly, the light does not spread and is absorbed by the charge accumulation region 202, whereby high sensitivity can be implemented. An optimal width of each optical waveguide is 710 nm, and an optimal height thereof is 610 nm.

Thus, satisfactory sensitivity characteristics can be implemented for all of the green, red, and blue pixels 151G, 151R, and 151B.

As in the examples of the first and second embodiments, a CMOS sensor etc. may be used as the solid-state imaging device 150b instead of a CCD, pixels of complementary colors may be used instead of pixels of primary colors, etc.

The solid-state imaging device 150b of the present embodiment is described with respect to an example in which the height of each optical waveguide is in the range of 600 nm to 620 nm, both inclusive. However, the present invention is not limited to this, and the height of each optical waveguide may be in the range of, e.g., 700 nm to 750 nm, both inclusive. In this case, the refractive indices of the core materials of each optical waveguide can be reduced by about 0.3 (from the values shown in the above example).

The optical waveguides having different refractive indices can be formed by, e.g., ion implantation to the core material. This will be described below.

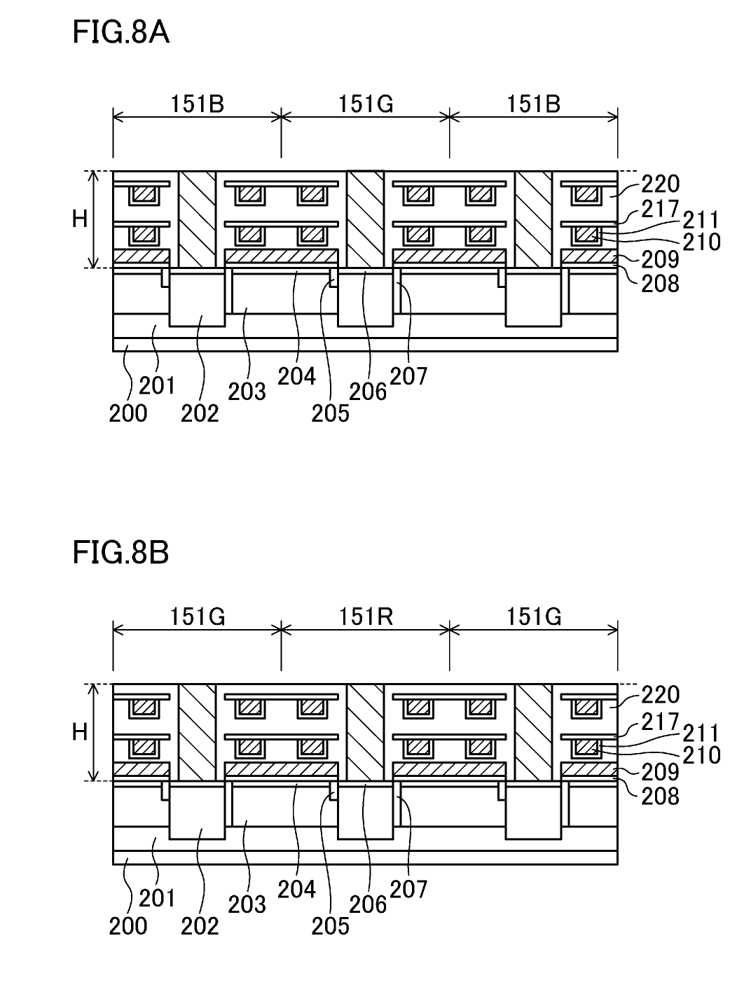

FIGS. 8A-8B are diagrams corresponding to FIGS. 7A-7B, showing the solid-state imaging device 150b during manufacturing. In the step of FIGS. 8A-8B, the same organic material (core material) is buried in the interlayer insulating film 220 on the charge accumulation region 202 of each pixel to form the optical waveguides having the same dimensions and shape. The core material has a refractive index of, e.g., 1.8.

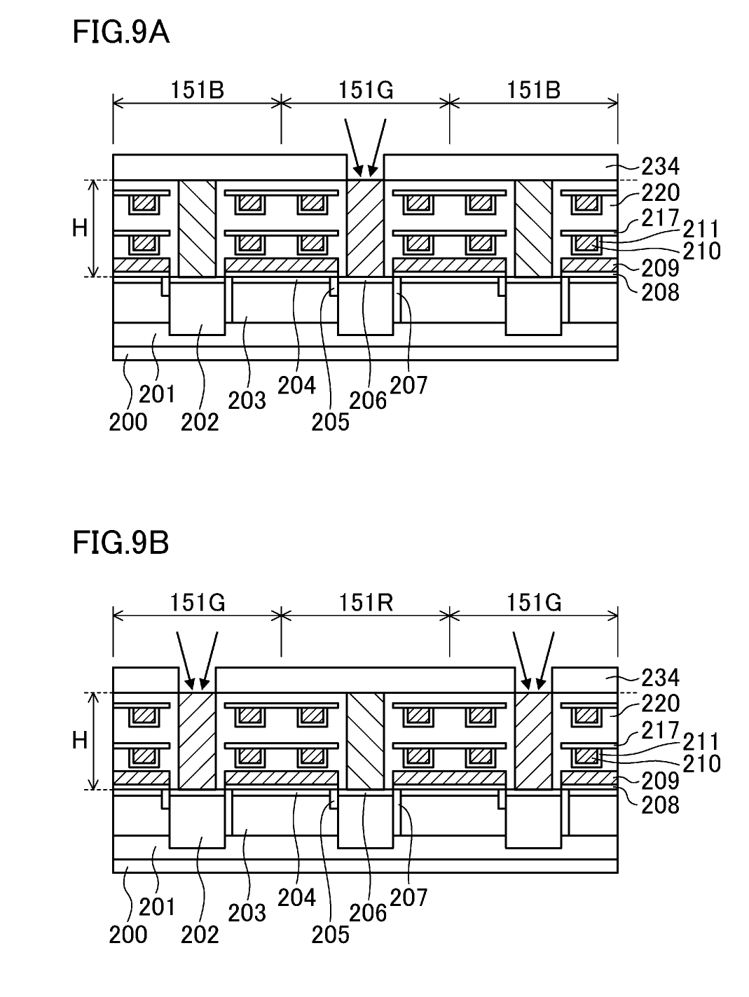

Then, as shown in FIGS. 9A-9B, ion implantation is performed only on the optical waveguide in the green pixel 151G. First, a resist 234 is formed so as to have an opening on the optical waveguide (the core material) in the green pixel 151G, and ion implantation is performed by using the resist 234 as a mask. For example, nitrogen ions are implanted at a dose of 1×10¹⁵ cm⁻² and implantation energy of 80 keV. This increases the refractive index of the core material in the green pixel 151G (the green pixel optical waveguide 218G) to about 2.2.

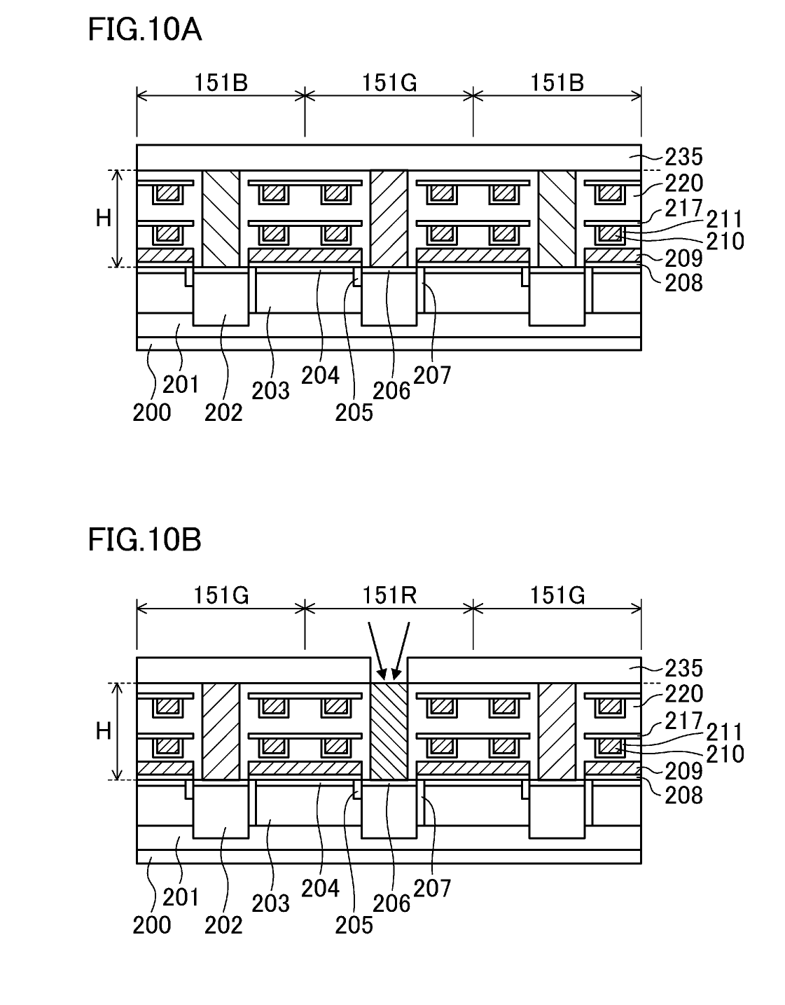

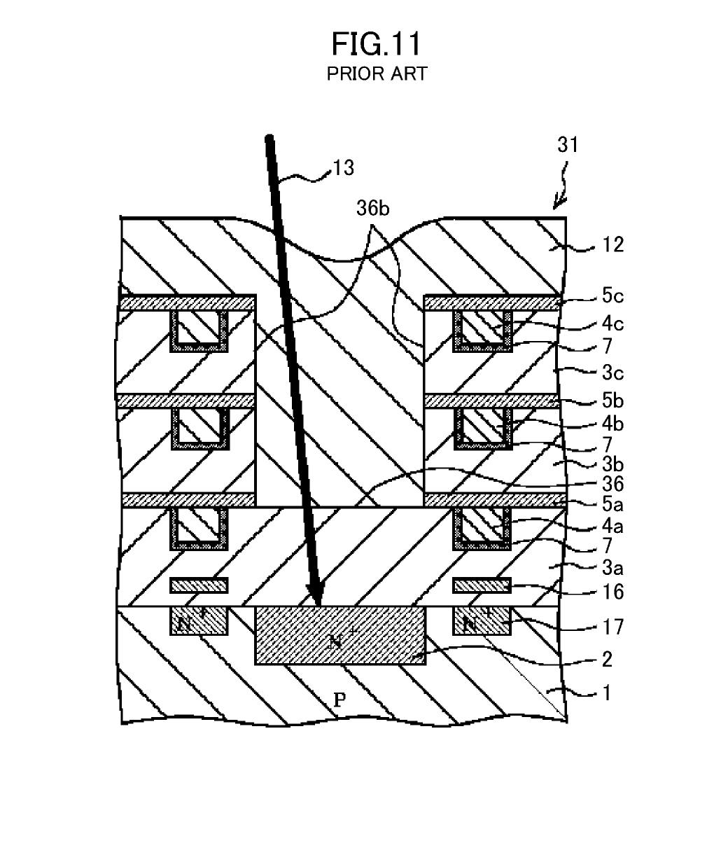

Then, after the resist 234 is removed, ion implantation is performed only on the optical waveguide in the red pixel 151R, as shown in FIGS. 10A-10B. In this case, a resist 235 is formed so as to have an opening on the optical waveguide in the red pixel 151R, and ion implantation is performed by using the resist 235 as a mask. For example, nitrogen ions are implanted at a dose of 5×10¹⁵ cm⁻² and implantation energy of 100 keV. The dose is larger than that used for the optical waveguide in the green pixel 151G in the step of FIGS. 9A-9B. This increases the refractive index of the core material in the red pixel 151R (the red pixel optical waveguide 218R) to about 2.6, which is higher than the refractive index of the green pixel optical waveguide 218G.

Thereafter, the resist 235 is removed. Moreover, a portion of the interlayer insulating film 220 which is located over the optical waveguides, the color filters 212, and the microlenses 153 are sequentially formed in a manner similar to that described in the first embodiment, whereby the solid-state imaging device 150b shown in FIGS. 7A-7B can be obtained.

In this manner, the optical waveguides can be provided which are comprised of the core material having different refractive indices in the pixels of each color (1.8 in the blue pixel optical waveguide 218B, 2.2 in the green pixel optical waveguide 218G, and 2.6 in the red pixel optical waveguide 218R).

An effective propagation wavelength of the optical wave in a waveguide is the product of the wavelength in vacuum and the reciprocal of the refractive index of the waveguide. Based on this, the same effective propagation wavelength can be implemented in every pixel. For example, the effective propagation wavelength with respect to the central wavelength is the same in every pixel. Specifically, 650×(1/2.8)=250 in the red pixel 151R, 550×(1/2.2)=250 in the green pixel 151G, and 450×(1/1.8)=250 in the blue pixel 151B.

In this case, the position of the single mode can be matched with the silicon surface in each optical waveguide 218 even if the optical waveguides 218 in the pixels corresponding to different wavelength bands have the same shape and dimensions (the width, the distance from the surface of the optical waveguide to the silicon surface). Accordingly, satisfactory sensitivity characteristics can be implemented in every pixel.

Although nitrogen ions are shown as an example of an ion species to be implanted, the present invention is not limited to this, and boron ions, fluorine ions, etc. may be used. The optical waveguides having different refractive indices may be formed by burying different core materials in the openings for forming optical waveguides which are formed in the interlayer insulating film 220. The use of different core materials may be combined with the ion implantation.

In the first, second, and third embodiments, sensitivity in each pixel is optimized by varying only one element, namely only one of the width of the optical waveguide 218, the height thereof, and the refractive index of the core. However, two or more of the elements may be varied. This increases design flexibility of the optical waveguides.

Propagation of light incident on the optical waveguides in actual solid-state imaging devices is not a simple phenomenon due to the influence of light collection by the microlenses, the influence of the light passing through many films such as the color filters, etc. However, as a basic principle, the mode that appears in the optical waveguide is determined by the width d of the waveguide, the wavelength λ in vacuum, the refractive index n1 of the core, and the refractive index n0 of the cladding. Accordingly, any of these elements may be varied.

The number of modes that are present in the simplest waveguide, namely a slab optical waveguide (the structure in which a flat plate-like core is interposed between flat plate-like claddings), can be obtained by the normalized frequency “v” represented by the following equation.

v=d/λ×π×\sqrt{(n1²−n0²)}

The single mode is obtained if “v” is in the range of 0 to 1/2π, both inclusive. Regarding the optical waveguides having structures other than the slab waveguide as well, an appropriate structure can be determined based on similar calculation, simulation, etc.

For example, in the case of solid-state imaging devices similar to those of the first to third embodiments, the green pixel optical waveguide 218G, the blue pixel optical waveguide 218B, and the red pixel optical waveguide 218R are made to have the same height in the range of 600 nm to 620 nm. Moreover, the refractive index of the core material is made to be the same in the range of 1.9-2.0 in the green pixel optical waveguide 218G and the blue pixel optical waveguide 218B, and is made to be in the range of 2.4-2.6 in the red pixel optical waveguide 218R. Moreover, the blue pixel optical waveguide 218B is made to have a width in the range of 580 nm to 620 nm, whereby the green pixel optical waveguide 218G and the red pixel optical waveguide 218R can be made to have the same width in the range of 700 nm to 740 nm. The refractive index of the interlayer insulating film 220 is in the range of 1.2-1.3.

Excessively reducing the width of the optical waveguide tends to cause problems such as degradation in burying property of the core material. The above configuration is advantageous in that excessive reduction in width of the red pixel optical waveguide 218R can be avoided, and that the ion implantation step need be performed only once.

The solid-state imaging device of the present disclosure is useful as multi-pixel, miniaturized solid-state imaging devices because sensitivity characteristics can be optimized for each of the pixels corresponding to different wavelength bands.

What is claimed is:

1. A solid-state imaging device, comprising:
a plurality of pixels arranged in a matrix pattern on a substrate, wherein each of the pixels includes
a photoelectric conversion portion configured to convert incident light to an electric signal,
an optical waveguide formed over the photoelectric conversion portion,
an interlayer insulating film formed around the optical waveguide, and a color filter formed over the optical waveguide,
the optical waveguide is configured so that light intensity distribution of light that has transmitted through the color filter has a single peak in a center of an upper surface of the photoelectric conversion portion, and
the plurality of pixels include at least two kinds of pixels that include the color filters configured to transmit light of different wavelength bands from each other therethrough.

2. The solid-state imaging device of claim 1, wherein
the at least two kinds of pixels include the optical waveguides having different widths from each other.

3. The solid-state imaging device of claim 2, wherein
the at least two kinds of pixels include a red pixel including the color filter configured to transmit red light therethrough, a blue pixel including the color filter configured to transmit blue light therethrough, and a green pixel including the color filter configured to transmit green light therethrough, and
the width of the optical waveguide is increased in order of the red, green, and blue pixels.

4. The solid-state imaging device of claim 1, wherein
the optical waveguides of the at least two kinds of pixels are comprised of materials having different refractive indices from each other.

5. The solid-state imaging device of claim 4, wherein
the pixel having the color filter configured to transmit the light of a shorter wavelength band has the optical waveguide comprised of the material having a lower refractive index.

6. The solid-state imaging device of claim 4, wherein
the at least two kinds of pixels include a red pixel including the color filter configured to transmit red light therethrough, a blue pixel including the color filter configured to transmit blue light therethrough, and a green pixel including the color filter configured to transmit green light therethrough, and
the refractive index of the material of the optical waveguide is increased in order of the blue, green, and red pixels.

7. The solid-state imaging device of claim 1, wherein
the at least two kinds of pixels include the optical waveguides having different heights from each other.

8. The solid-state imaging device of claim 7, wherein
the pixel having the color filter configured to transmit the light of a shorter wavelength band has the optical waveguide having a greater height.

9. The solid-state imaging device of claim 7, wherein
the at least two kinds of pixels include a red pixel including the color filter configured to transmit red light therethrough, a blue pixel including the color filter configured to transmit blue light therethrough, and a green pixel including the color filter configured to transmit green light therethrough, and
the height of the optical waveguide is decreased in order of the red, green, and blue pixels.

10. The solid-state imaging device of claim 1, wherein
the optical waveguide is in a shape of a cuboid or a cylinder.

11. The solid-state imaging device of claim 1, wherein
each of the pixels further includes a microlens provided above the optical waveguide, and
the color filter is located between the optical waveguide and the microlens or on the microlens.
